(19) United States
(12) Patent Application Publication
(10) Pub. No.: US 2004/0004816 A1
(43) Pub. Date: Jan. 8, 2004

(54) Method for waterproofing power circuit section and power module

(75) Inventors: Jun Yamaguchi, Mie (JP); Shinji Kawakita, Mie (JP); Takahiro Onizuka, Aichi (JP)

Correspondence Address: OLIFF & BERRIDGE, PLC, P.O. BOX 19928, ALEXANDRIA, VA, 22320, US

(73) Assignees: AUTONETWORKS TECHNOLOGIES, LTD., Nagoya-shi (JP); SUMITOMO WIRING SYSTEMS, LTD., Yokkaichi-shi (JP); SUMITOMO ELECTRIC INDUSTRIES, LTD., Osaka-shi (JP)

(21) Appl. No.: 10/611,547

(22) Filed: Jul. 2, 2003

(30) Foreign Application Priority Data
Jul. 3, 2002 (JP) 2002-194835
Feb. 14, 2003 (JP) 2003-037036

(51) Int. Cl. H05K 7/20

(52) U.S. Cl. 361/695

(57) ABSTRACT

A power circuit section including electronic parts of a plurality of FETs and relays having leg terminals is arranged in a circuit arrangement region on a heat radiating member. A surrounding wall member having a seal member at a lower end face thereof and capable of surrounding the power circuit section 1 including the leg terminals of the electronic parts is attached to surround the circuit arrangement region in a state of bringing a seal member into close contact with a circuit arrangement surface. After a circuit arranging step and a surrounding wall forming step, a waterproofing resin in a liquid state is poured into a space surrounded by the surrounding wall member until at least the leg terminals of the electronic parts are sealed. The waterproof resin is cured to form a waterproofing layer for sealing the electronic parts.

### BACKGROUND OF THE INVENTION

1. Field of the Invention

The present invention relates to a method for waterproofing a power circuit section having an electronic part of a relay switch, a semiconductor element or the like and arranged on a heat radiating member, for example, relates to a method for waterproofing a power circuit section for distributing power from a common in-vehicle power source to a plurality of electronic units.

2. Description of the Related Art

Conventionally, as means for distributing power from a common in-vehicle power source to respective electronic units, there has been known an electronic connection box in which a power circuit section is constituted by laminating a plurality of sheets of bus bar boards and integrated with a fuse or a relay switch.

Such an electronic connection box generally contains the power circuit section at inside of a case constituted by a lower case and an upper case and achieves waterproof at inside of the case by fitting the lower case and the upper case water-tightly from a view point of preventing short-circuit or the like.

Meanwhile, in recent years, in order to realize small-sized formation and high speed switching control of such an electric connection box, there has been developed a power module interposing a semiconductor switching element of FET or the like between an input terminal and an output terminal in place of the relay or along with the relay. There has been proposed the power module constituted by arranging a power circuit section on a circuit arrangement surface of a heat radiating member via an insulating layer from a view point of cooling heat generated from the semiconductor element (for example, JP-A-11-204700).

With regard to the above-described power module, it is necessary to prevent short-circuit from being submerged as with the above-described conventional electronic connection box. Therefore, although waterproof performance of the circuit section is requested, a specific method of waterproofing has not been disclosed yet.

Here, it is possible to waterproof the power module by containing the power module at inside of the case including a lower case and an upper case and integrating a strict waterproof structure with the case as with the above-described conventional electric connection box. However, when such strict waterproof structure is incorporated thereinto, the structure of the power module becomes complicated and time and labor is needed for carrying out waterproof processing. Furthermore, the waterproof cannot simply be carried out and compact formation of the power module becomes difficult.

### SUMMARY OF THE INVENTION

It is an object of the invention to provide a method for waterproofing a power circuit section capable of achieving effective waterproof by a simple method and capable of satisfying a request for small-sized formation of a power module.

In order to resolve the above-described problem, a method according to embodiments of the invention waterproofs a power circuit section. The method includes arranging the power circuit section including at least one electronic part having a plurality of leg portions in a circuit arrangement region on a circuit arrangement surface of a heat radiating member; attaching a wall member, which is made of an insulating material and includes a seal member at an end surface on a side of the heat radiating member, to the heat radiating member in a state where the wall member surrounds the circuit arrangement region and the seal member is closely contacted with the circuit arrangement surface; pouring a liquid resin into a space surrounded by the wall member and the heat radiating member until at least the leg portions of the electronic part are sealed; and curing the resin to form a waterproof layer.

With the above described method, after the arranging step and the attaching step, the waterproofing resin in the liquid state is poured into the space surrounded by the wall member and the heat radiating member to seal at least the leg portion of the electronic part and the waterproofing resin is cured to form the water proofing layer. Therefore, a surrounding wall, that is, a dam surrounding the circuit arrangement region can be formed by only attaching the wall member made of the insulating material to the heat radiating member. Also, the power circuit section can be waterproofed only by pouring the waterproofing resin in the liquid state into the space surrounding by the dam and curing the waterproofing resin. Therefore, effective waterproofing of the power circuit section can be achieved by a simple method. Further, the waterproofing resin in the liquid state is employed. Therefore, the waterproofing resin spreads to corners and the waterproofing layer can firmly be formed over the entire power circuit section. Further, the surrounding wall member may include the seal member at the end surface. The seal member is attached to the heat radiating member in the state of being brought into close contact with the circuit aligning face. Therefore, even when there is a clearance between the surrounding wall member and the heat radiating member, the clearance is closed by the seal member and the waterproofing resin in the liquid state can be prevented from being leaked. As a result, the leg portions of the electronic part can firmly be sealed by only pouring a predetermined amount of the waterproofing resin. Further, waterproofing of the power circuit section is achieved by forming the waterproofing layer by curing the waterproofing resin. Therefore, the power module can compactly be formed and also the request for the small-sized formation of the power module can be satisfied.

According to the embodiments of the invention, the wall member may include a groove on the side of the heat radiating member. In the attaching step, the wall member may be attached to the heat radiating member after the seal member is attached to the groove. When constituted in this way, the waterproofing resin in the liquid state can further firmly be prevented from being leaked by the seal member. Further, the surrounding wall member can be attached to the heat radiating member in the state of holding the seal member in the groove of the surrounding wall member. The seal member can be interposed therebetween firmly and at a desired position.

The seal member is not particularly limited so far as the seal member can prevent the waterproofing resin from being leaked by being interposed between the surrounding wall member and the heat radiating member. However, it is preferable to use foamed rubber having constant elastic performance from a view point that when a local clearance is present between the wall member and the heat radiating member, the clearance can firmly be prevented. Further, the seal member may be able to temporarily prevent the waterproofing resin from being leaked during a time period in which the waterproofing resin in the liquid state is filled and cured. Therefore, durability over a long period of time is not requested and a comparatively inexpensive material, for example, chloroprene rubber can be used.

Further, according to the embodiments of the invention, it is preferable that the waterproofing resin used in the waterproofing layer forming step is a silicone resin. When constituted in this way, not only the waterproofing layer is excellent in heat resistance and cold resistance and electric insulating performance thereof is also improved.

According to the embodiments of the invention, it is preferable that after the waterproofing layer forming step, a lid is attached to an opening portion of the wall member to cover the opening portion, wherein the opening portion is formed on an opposite side of the wall member to the heat radiating member. When constituted in this way, a case can be formed by effectively utilizing the wall member and the power circuit section can be protected effectively against outside shock.

Further, according to the embodiments of the invention, the following construction is preferable. The power circuit section includes a bus bar constitution plate on which a plurality of bus bars are arranged in a predetermined pattern; an electronic part disposed on the bus bar constitution plate; and a control circuit board for controlling a switching operation of the electronic part, the control circuit board bonded to one surface of the bus bar constitution plate. The electronic part is mounted to the bus bar constitution plate and the control circuit board. In the pouring step, the resin is poured until the bus bar constitution plate and the control circuit board are sealed. When constituted in this way, the power circuit section can be formed thin. Therefore, by a comparatively small amount of the waterproofing resin, the waterproofing resin is poured to reach a state of sealing the leg portions of the electric part including the bus bar constituting plate and the control circuit board and firm and effective waterproofing of the power circuit section can be achieved at low cost.

### BRIEF DESCRIPTION OF THE DRAWINGS

FIG. 1 is a sectional view showing a power module to which a method of waterproofing a power circuit section according to a first embodiment of the invention is applied.

FIG. 2 is a plane view showing the power module in a state after a circuit arranging step.

FIG. 3 is a view enlarging an essential portion of FIG. 1.

FIG. 4 is a perspective view showing FET in a state of sealing a leg-like terminal thereof by a waterproofing resin.

FIG. 5 is a top view showing a structure of connecting a second external connection terminal in the power module.

FIG. 6 is a perspective view showing a power module to which a method of waterproofing a power circuit section according to a second embodiment of the invention is applied in a disassembled state.

FIG. 7 is a perspective view showing a surrounding wall member, a seal member and a heat radiating member of the power module in a disassembled state.

FIG. 8 is a perspective view showing the surrounding wall member of the power module.

FIG. 9 is a sectional view of an essential portion of the power module.

### DETAILED DESCRIPTION OF THE PREFERRED EMBODIMENTS

Preferable embodiments of the invention will be explained with reference to the drawings. Further, although a power circuit section for distributing power supplied from a common power source mounted to a vehicle to a plurality of electric loads is shown here, use of a power circuit section according to the invention is not limited thereto but the invention is applicable widely to a power circuit section requesting heat radiation and waterproof.

### First Embodiment

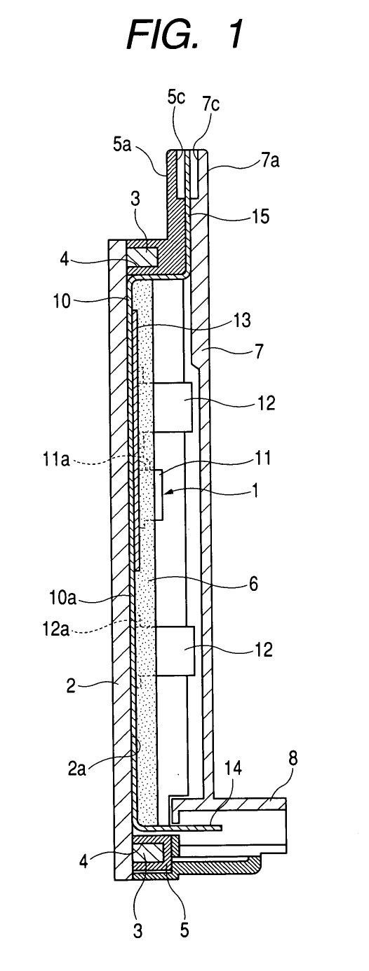

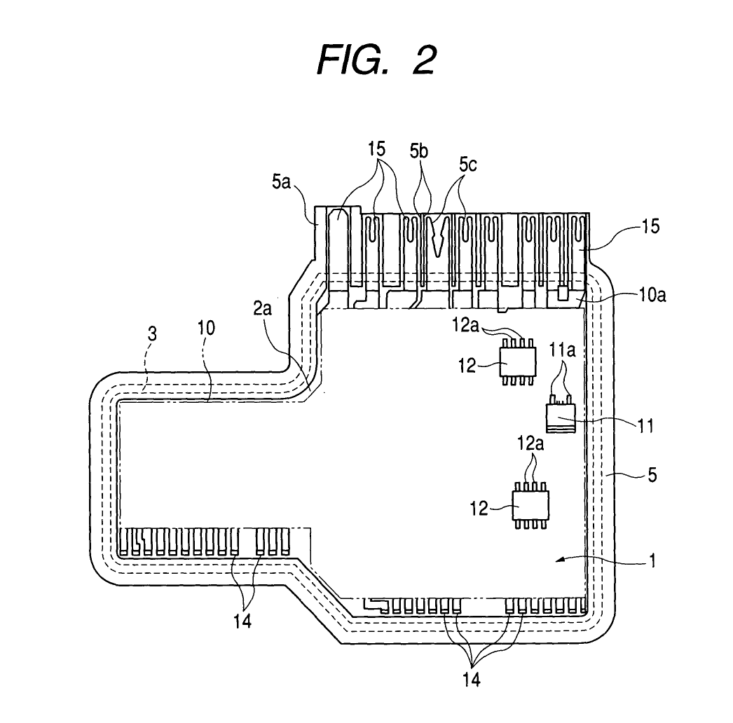

FIG. 1 is a sectional view showing a power module including a power circuit section subjected to a waterproofing processing by a waterproofing method according to a first embodiment. FIG. 2 is a plane view of the power module in a state after a circuit arranging step, described later.

Although according to the first embodiment, the power module is mounted to a vehicle by being vertically arranged, that is, by directing an upper portion in FIG. 1 to an upper side, a direction of mounting the power module to a vehicle is not limited thereto. Although in the following explanation, a direction in a case of vertically arranging the power module is also used, the direction is conveniently used to specify a relative direction between respective members.

First, as shown in FIG. 1 and FIG. 2, a predetermined power circuit section 1 waterproofed by the waterproofing method according to the first embodiment includes a bus bar constituting plate 10, a plurality of FETs 11, a plurality of relays, and a control circuit board 13. In the bus bar constituting plate 10, a plurality of sheets of bus bars 10a are aligned in a predetermined pattern in the same plane at inside of a region having a predetermined polygonal shape (according to the embodiment, a convex shape rotated in a clockwise direction). In the embodiment, the predetermined pattern is a pattern in which end portions of the bus bars 10a are projected from two side edges of the region (in FIG. 1, two upper and lower side edges). The FETs 11 are semiconductor switching elements interposed between the bus bar 10a for an input terminal and the bus bar 10a for an output terminal among the bus bars 10a constituting the bus bar constituting plate 10. The relays 12 are interposed between a plurality of predetermined bus bars 10a. The control circuit board 13 is adhered to one face (right side face in FIG. 1) of the bus bar constituting plate 10 to control switching operation of the FETs 11 and a part of the relays 12. The FETs 11 and the part of the relays 12 are mounted to both of the bus bar constituting plate 10 and the control circuit board 13, that is, electrically connected thereto.

As shown in FIG. 1 and FIG. 2, the FET 11 is formed substantially in a shape of a parallelepiped. A plurality (two pieces according to the embodiment) of terminals 11a in a leg-like shape are projected from a side face thereof. The terminals 11a are electrically connected to the bus bar constituting plate 10 and the control circuit board 13. On the other hand, the relay 12 has substantially a parallelepiped shape. A plurality (eight pieces according to the embodiment) of terminals 12a in a leg-like shape are provided to project in side directions along the bus bar constituting plate 10 at a lower end portion thereof. These are electrically connected to the bus bar constituting plate 10.

The power circuit section 1 includes external connection terminals 14 and 15 to which other external terminals are connected and which serve, for example, as input terminals, output terminals or signal input terminals. The external connection terminals 14 and 15 are formed by bending end portions of the predetermined bus bars 10a in a predetermined shape. In the first embodiment, the external connection terminals include the first external connection terminal 14 projected from a lower end edge of the bus bar constituting plate 10 in a right side direction (projected to a side opposed to a side of a heat radiating member 2, described later). The second external connection terminal 15 bent and formed in an L shape at an upper end edge of the bus bar constituting plate 10 and projected in an upper direction and connected with external terminals from the upper direction and the right side direction of the power module. As shown in FIG. 2, the second external connection terminal 15 includes a terminal a front end portion of which is formed in a bifurcated shape to facilitate to insert an external terminal similarly formed in a bifurcated shape.

The shape of the bus bar constituting plate 10 and the pattern of arranging the bus bar 10a can pertinently be changed. Also, the FET 11 or the relay 12 can be changed to other electronic part having a leg terminal such as LSI, thyrister or the like. Further, the control circuit board 13 can also be arranged at a position on an upper side of FET 11.

1) Heat radiating member forming step

First, the heat radiating member 2 which the power circuit section 1 waterproofed by the waterproofing method according to the first embodiment is arranged on is formed.

That is, the heat radiating member 2 formed by this step has the convex shape rotated. For example, the entire heat radiating member 2 is formed of a material excellent in heat conductivity such as an aluminum series metal. An upper face of the heat radiating member 2 is formed to be flat to constitute as a circuit arrangement surface 2a. A circuit arrangement region on which the power circuit section 1 is arranged is provided on the circuit arrangement surface 2a. An insulating layer (not illustrated) is provided in a state of protruding from the region. The circuit arrangement region refers to a predetermined region on the circuit arrangement surface 2a on which the power circuit section 1 is arranged in a circuit arranging step, described later. In the first embodiment, the insulating layer is provided at one face thereof. The insulating layer is thermally connected to the heat radiating member 2. For example, the insulating layer is formed by coating and drying an adhering agent having high insulating performance (for example, an adhering agent comprising an epoxy species resin, a silicone specifies adhering agent) or by pasting an insulating sheet on the circuit arrangement surface 2a.

The heat radiating member 2 may be formed to have a heat radiating fin or a heat radiating pin, which protrudes, on a side thereof opposed to the circuit arrangement surface 2a to thereby enhance a heat radiating efficiency.

2) Surrounding wall forming step

Next, a predetermined surrounding wall member 5 is attached to the circuit arrangement region of the heat radiating member 2 via a seal member 3.

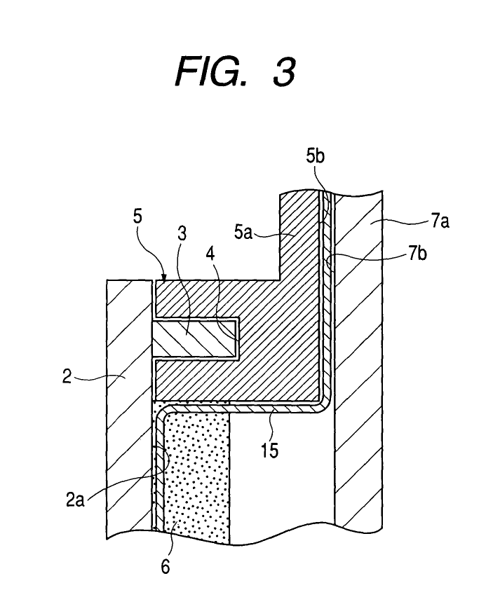

That is, first, as shown in FIG. 1 through FIG. 3, the predetermined surrounding wall member 5 including a seal member filling groove 4 at an end face thereof on a side of the heat radiating member 2 is formed.

The surrounding wall member 5 formed of an insulating material. As shown in FIGS. 1 and 2, the surrounding wall member 5 is formed in a cylindrical shape to be along a peripheral edge portion of the circuit arrangement surface 2a of the heat radiating member 2. It is possible for the surrounding wall member 5 to surround the power circuit section 1. That is, the surrounding wall member 5 has a shape of surrounding the circuit arrangement region of the heat radiating member 2. Further, the surrounding wall member 5 is formed such that a height of a peripheral side wall thereof is higher than the leg-like terminals 11a and 12a of the various electronic parts 11 and 12 (in the embodiment, FET 11 and the relay 12) mounted to the power circuit section 1, and preferably formed to be higher than heights of the various electronic parts 11 and 12. That is, the surrounding wall member 5 is formed to be able to surround the power circuit section 1 including at least the leg-like terminals 11a and 12a of the various electronic parts 11 and 12. In the first embodiment, the height of the surrounding wall member 5 is formed to be a little bit lower than that of the relay 12 mounted to the power circuit section 1.

Further, as shown in FIG. 1 and FIG. 2, the surrounding wall member 5 is provided with the seal member filling groove 4 at the end face on the side of the heat radiating member 2 over an entire periphery thereof along the end face. The seal member 3 is fitted to the seal member filling groove 4. Although a sectional shape of the seal member filling groove 4 is not particularly limited, in the embodiment, the sectional shape is formed substantially in a U shape.

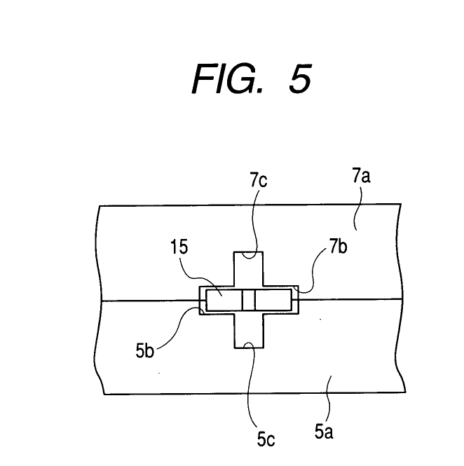

Further, as shown in FIG. 1, FIG. 2 and FIG. 5, the surrounding wall member 5 is provided with a wall side flange portion 5a projected in the upper direction. The wall side flange portion 5a is formed a wall side guide groove 5b for guiding the second external connection terminal 15. A terminal holding groove 5c is provided substantially at a center of the wall side guide groove 5b in a width direction thereof along a longitudinal direction thereof.

The seal member 3 is formed in a ring shape surrounding the circuit arrangement region and is formed to be able to fit tightly to the seal member filling groove 4. The seal member 3 is provided for temporarily preventing a waterproofing resin from being leaked from the surrounding wall member 5 until the waterproofing resin in a liquid state, described later, is cured. Therefore, durability of the seam member 3 over a long period of time is not requested and a comparatively inexpensive seal member can be used therefor. Although the seal member 3 is not particularly limited, from a view point of firmly closing a clearance between the surrounding wall member 5 and the heat radiating member 2, the seal member having constant elastic performance, for example, foamed rubber having independent air bubbles is preferably used. Further, also the material used for the seal member 3 is not particularly limited and chloroprene rubber or the like is preferably used from view points of economic performance, general purpose performance, workability and the like.

Further, the surrounding wall member 5 is attached to the heat radiating member 2 in a state of fitting the seal member 3 to the seal member filling groove 4 of the surrounding wall member 5 tightly. Thereafter, the surrounding wall member 5 is attached to the heat radiating member 2 in a state where the surrounding wall member 5 surrounds the circuit arrangement region and the seal member 3 is close-tightly contacted to the circuit arrangement surface 2a. In attaching the surrounding wall member 5 to the heat radiating member 2, for example, a appropriate portion of the surrounding wall member 5 may be attached thereto by a mechanical fixing member of a screw, a bolt or the like, or may be attached thereto by adhesion or the like and a publicly-known attaching method is adopted therefor. Also, when a waterproofing resin, described later, having adhering performance is used, the surrounding wall member 5 may be attached to the heat radiating member 2 by tacking.

Accordingly, when the surrounding wall is attached onto the circuit arrangement surface 2a of the heat radiating member 2, as shown in FIG. 1 and FIG. 2, a surrounding wall is formed by the surrounding wall member 5 to surround the circuit arrangement region of the circuit arrangement surface 2a of the heat radiating member 2 and the surrounding wall functions as a dam.

3) Circuit arranging step

The power circuit section 1 is arranged on the circuit arrangement region surrounded by the surrounding wall member 5. Specifically, the power circuit section 1 is bonded using, for example, an adhering agent having high conductivity while the second external connection terminal 15 thereof is received in the wall side guide groove 5b of the surrounding wall member 5. If the bus bars 10a includes a bus bar, which should be earthed, the bus bars 10a are screwed onto the heat radiating member 2 to arrange the bus bars 10a in the circuit arrangement region on the circuit arrangement surface 2a of the heat radiating member 2 through the insulating layer. In other words, the power circuit section 1 is arranged to be fitted into a space surrounded by the surrounding wall member 5.

4) Waterproofing layer forming step

After the surrounding wall forming step and the circuit arranging step, a predetermined amount of a waterproofing resin is poured in a liquid state into the space surrounded by the surrounding wall member 5 and is cured to form a waterproofing layer 6.

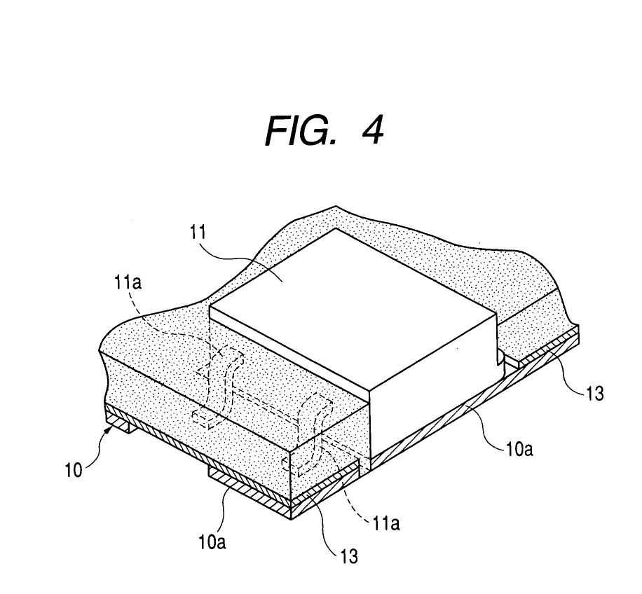

Specifically, first, the heat radiating member 2, which the surrounding wall member 5 is attached to and the power circuit sections 1 is arranged on is set such that a side of the circuit arrangement surface 2a thereof is directed in the upper direction. Then, the waterproofing resin in the liquid state is poured from an opening portion of the surrounding wall member 5 on a side opposed to the side of the heat radiating member 2, that is, from an upper end opening portion thereof. The waterproofing resin is poured until the leg-like terminals 11a and 12a of the various electronic parts 11 and 12 mounted to the power circuit section 1 are sealed. FIG. 4 is a perspective view showing a state in which the leg-like terminal 11a of FET 11 among the various electronic parts 11 and 12 is sealed. In the state of being filled with the waterproofing resin, also the bus bar constituting plate 10 and the control circuit board 13 except the first and the second external connection terminals 14 and 15 are sealed by the waterproofing resin.

A material of the waterproofing resin is not particularly limited. A silicone series resin may preferably be used from view points of being not only excellent in heat resistance and cold resistance but also excellent in electric insulating performance. Further, when the waterproofing resin having adhering performance is adopted, operation can further be simplified by omitting operation of coating a primer. Further, when the waterproofing resin excellent in heat conductivity is adopted, not only heat radiation by the heat radiating member 2 is accelerated but also heat is radiated from the waterproofing layer 6 to thereby enable to achieve further excellent heat radiating performance.

Next, the poured waterproofing resin is heated and cured to form the waterproofing layer 6. In the first embodiment, whereas the waterproofing resin is provided with constant elastic performance after having been cured, the waterproofing resin is also provided with constant shape holding performance and is maintained in a state of sealing the power circuit section 1 except the first and the second external connection terminals 14 and 15 as shown in FIG. 1.

5) Lid member attaching step

Further, a lid member 7 for covering an opening portion of an upper end of the surrounding wall member 5 is fabricated and the waterproofing member 6 is formed. Thereafter, the lid member 7 is attached to the surrounding wall member 5 in a state of covering the opening portion of the upper end of the surrounding wall member 5.

The lid member 7 has a shape of a convex plate rotated in correspondence with the opening portion of the upper end of the surrounding wall member 5 and includes a lid side flange portion 7a to overlap the wall side flange portion 5a of the surrounding wall member 5. The lid side flange portion 7a is provided with a lid side guide groove 7b for guiding the second external connection terminal 15. The second external connection terminal 15 is contained in a space formed between the lid side guide groove 7b and the wall side guide groove 5b. Also, the lid side guide groove 7b includes a terminal holding groove 7c, into which an external terminal is inserted to hold the external terminal, along a longitudinal direction of the guide groove 7b.

Further, the lid member 7 includes a hood 8 for connecting a connector formed in correspondence with the first external connection terminal 14 at a lower end portion thereof. That is, as shown in FIG. 1, the lower end portion of the lid member 7 includes the hood 8 in a cylindrical shape projected in the right side direction. One or a plurality of the first external connection terminals 14 are constituted to be able to project into the hood 8. The hood 8 and one or a plurality of the first external connection terminals 14 constitute an external connection connector, which can connect with another connector.

The lid member 7 is attached to the surrounding wall member 5 by a locking member such as a locking piece (not illustrated), or attached to the surrounding wall member 5 by adhesion or welding.

Further, although the lid member 7 can pertinently be omitted, it is preferable to provide the lid member 7 from a view point of avoiding inside of the surrounding wall member 5 from being exposed and protecting the power circuit section 1 against outside shock.

In the power module formed as described above, by connecting a power source and/or an electric load to the first and the second external connection terminals 14 and 15, a power distributor for distributing power from the power source to pertinent electric loads is constructed. In the first embodiment, particularly when the power source, the electric load or the like is connected to the second external connection terminal 15 as shown in FIG. 5, by inserting an external terminal in a bifurcated shape into a terminal holding hole formed in the terminal holding grooves 5c and 7c formed in the wall side guide groove 5b and the lid side guide groove 7b, the both members can easily be connected.

According to the method for waterproofing the power circuit section 1 as described above, the surrounding wall member 5 surrounds the circuit arrangement region on the circuit arrangement surface 2a of the heat radiating member 2 to form a dam, while the power circuit section 1 is arranged in the circuit arrangement region of the circuit arrangement surface 2a through the insulating layer. Thereafter, the water proofing resin in the liquid state is poured into the space surrounded by the surrounding wall member 5 until at least the leg-like terminals 11a and 12a of FET 11 and the relay 12 are sealed, and the waterproof resin is cured to form the waterproofing layer 6. Therefore, the power circuit section 1 can be waterproofed by only puoring the waterproofing resin in the liquid state into the space surrounded by the dam formed of the surrounding wall member 5 and curing the waterproofing resin. Therefore, waterproofing of the power circuit section 1 can be achieved by the simple method. Further, since the silicone series resin in the liquid state is adopted for the waterproofing resin, the resin can be spread to corners in the space surrounded by the dam and the waterproofing layer 6 can firmly be formed over the entire power circuit section 1 to achieve waterproofing the power circuit section 1. Further, since the surrounding wall member 5 is attached to the heat radiating member 2 via the seal member 3, that is, the seal member 3 is interposed between the both members 2 and 5, even when there is a clearance locally between the both members 2 and 5, the clearance is closed by the seal member 3 and the waterproofing resin in the liquid state can be prevented from being leaked. Therefore, the waterproofing layer 6 having a desired height can be formed by a predetermined amount of the waterproofing resin. When the height thereof is set in consideration of the leg-like terminals 11a and 12a of FET 11 and the relay 12, the leg-like terminals 11a and 12a can firmly be sealed. Further, the seal member 3 is held by the seal member filling groove 4 of the surrounding wall member 5, and the surrounding wall member 5 is attached to the heat radiating member 2 under this state. Therefore, the seal member 3 can be interposed firmly between the surrounding wall member 5 and the heat radiating member 2.

Further, the power circuit section 1 waterproofed by the water proofing layer 6 includes the bus bar constituting plate 10, FET 11, the relay 12, and the control circuit board 13 adhered to one face of the bus bar constituting plate 10 for controlling the switching operation of FET 11. FET 11 is mounted to both of the bus bar constituting plate 10 and the control circuit board 13. Therefore, the power circuit section 1 can be formed compactly, particularly compactly in the thickness direction. Accordingly, a comparatively small amount of waterproofing resin is required to seal the leg-like terminals 11a and 12a of FET 11 and the relay 12. Thus, waterproofing of the power circuit section 1 can be achieved at low cost.

Further, waterproofing of the power circuit section 1 is achieved by curing the waterproofing resin to form the waterproofing layer 6. Therefore, the power module can be formed as small as possible.

### Second Embodiment

Next, a method for waterproofing a power circuit section according to a second embodiment of the invention will be explained as follows.

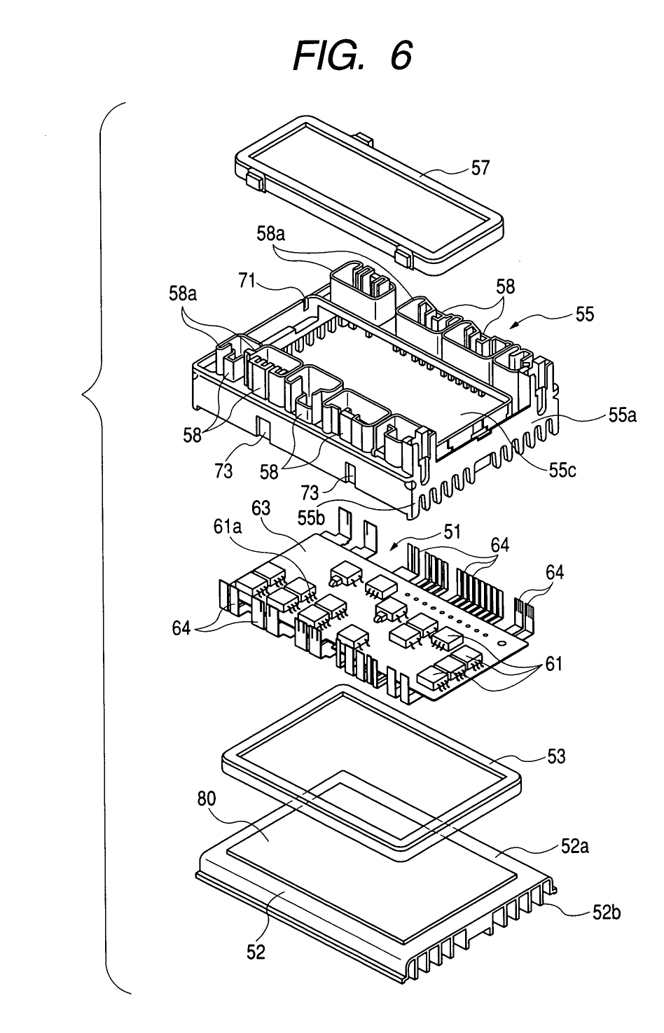

The method for waterproofing a power circuit section according to the second embodiment differs from the above-described first embodiment in a specific constitution of a power module including a power circuit section to be waterproofed. Further, also with respect to a specific order in the waterproofing method, the second embodiment differs from the first embodiment in that by assembling a power circuit section 51 to a surrounding wall member 55 and assembling the surrounding wall member 55 in the assembled state to a heat radiating member 52, the power circuit section 51 is arranged on the heat radiating member 52 and a surrounding wall is formed at the heat radiating member 52. An explanation will be given on the second embodiment with emphasis on a portion different from the first embodiment as follows. FIG. 6 is a perspective view showing to disassemble a power module including the power circuit section 51 subjected to waterproofing processing by the waterproofing method according to the second embodiment. Further, in the second embodiment, also the power module is mounted to a vehicle to be arranged vertically, that is, by constituting an upper side thereof by a short side on this side in FIG. 6 and an explanation will be given conveniently in directions in the drawings unless specified otherwise.

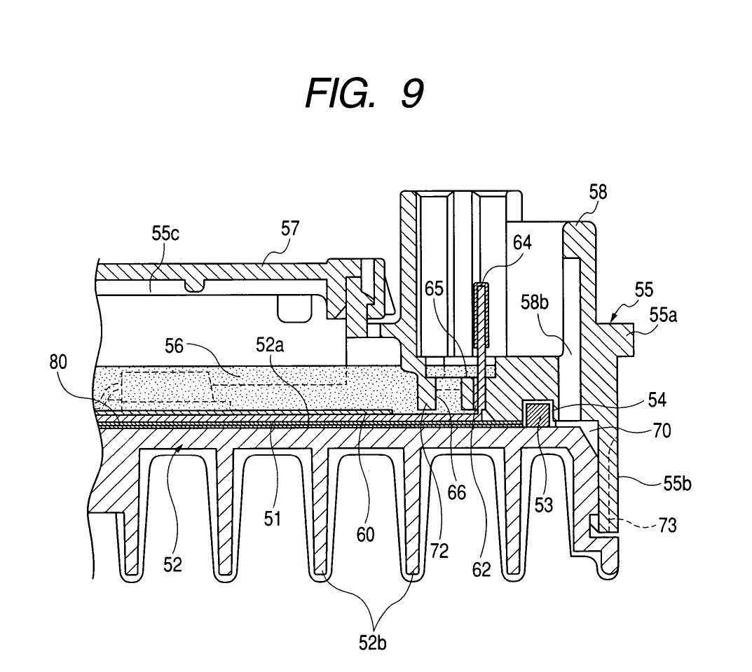

First, as shown in FIG. 6 and FIG. 9, the predetermined power circuit section 51 waterproofed by the waterproofing method according to the second embodiment includes a plurality of bus bars 60, a plurality of FETs 61, and a control circuit board 63. The bus bars 60 are aligned in a region substantially in a rectangular shape and on the same plane in a predetermined pattern, that is, in a pattern in which end portions of the bus bars 60 are projected from both left and right side edges of the region. The FETs 61 are semiconductor switching elements interposed between the bus bars 60 for input terminals and the bus bars 60 for output terminals among the bus bars 60. The control circuit board 63 is adhered to one face (upper face in FIG. 6) of the bus bar 60 and has a control circuit for controlling switching operation of the FETs 61. The FET 61 is mounted to both of the bus bars 60 and the control circuit board 63, that is, electrically connected thereto.

The power circuit section 51 is also formed an external connection terminal 64 constituted by bending an end portion of the bus bar 60 in a predetermined shape (in FIG. 6, bent to an upper side) and connected with other external terminal. In the second embodiment, the external connection terminals 64 are formed at left and right side edges of the region on which the bus bars 60 are arranged in a state of being arranged vertically to project in side directions. Similar to the first embodiment, the external connection terminal 64 serves as an input terminal, an output terminal or a signal input terminal.

Constitution of the power circuit section 51 is not limited to that in the second embodiment as with the first embodiment.

1) Heat radiating member forming step

First, the heat radiating member 52 on which the power circuit section 51 to be waterproofed by a waterproofing method of the second embodiment is arranged is formed.

That is, the heat radiating member 52 formed at this step differs from the heat radiating member 2 according to the first embodiment in that a plurality of heat radiating fins 52b aligned in a left and right direction are provided to project downward from a lower face thereof. A number of FETs 61 are mounted to the power circuit section 51 according to the second embodiment. The reason why the heat radiating fins 52b is provided as described above is to radiate heat generated by the FETs 61 efficiently. Further, the heat radiating fins 52b may pertinently be omitted also in the second embodiment. Alternatively, the heat radiating fin 52 may be constituted to enhance a heat radiating efficiency by enlarging a surface area of the heat radiating fin 52b and aligning a number of narrow grooves in the heat radiating fin 52.

Further, a circuit arrangement region on which the power circuit section 51 is arranged is provided also on a circuit arrangement surface 52a of the heat radiating member 52 according to the second embodiment. An insulating layer 80 is provided to protrude from the region. The insulating layer 80 is thermally connected to the heat radiating member 52 and formed by, for example, coating and drying an adhering agent having high insulating performance. Particularly, in the second embodiment, when an adhering agent (adhering agent in the embodiment) bonding the power circuit section 51 to the heat radiating member 52 is used as the insulating layer 80, the insulating layer 80 can firmly be formed. That is, even when pin holes are brought about in forming the insulating layer 80, the pin holes are filled during an operation of coating an adhering agent, described later, and the adhering agent for adhering the power circuit section 51 constitutes a portion of the insulating layer 80. Therefore, the power circuit section 51 and the heat radiating member 52 can firmly be insulated from each other.

2) Surrounding wall forming step and circuit arranging step

Next, the predetermined surrounding wall member 55 is attached to the circuit arrangement region of the heat radiating member 52 via a seal member 53 in a state of assembling the power circuit section 51 to the surrounding wall member 55.

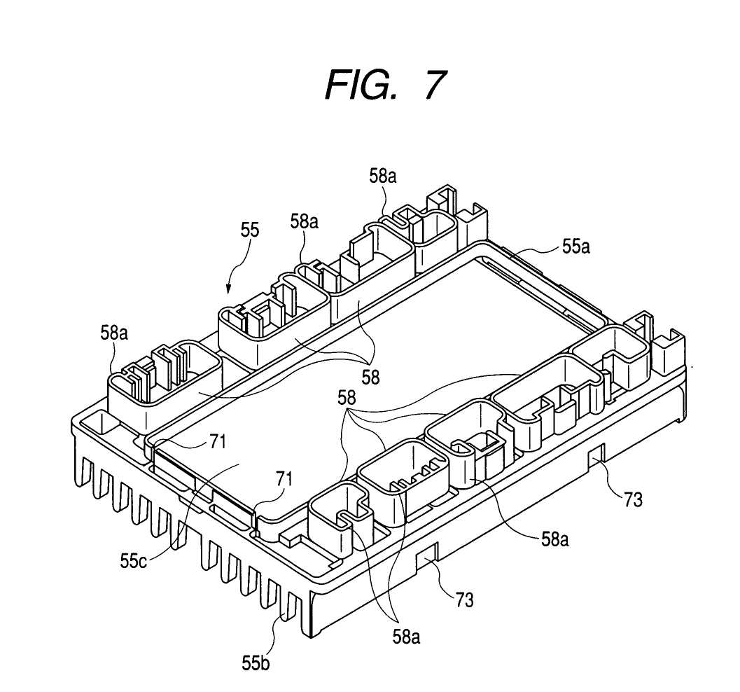

That is, first, the surrounding wall member 55 as shown in FIG. 6 through FIG. 8 is formed. The surrounding wall member 55 formed of an insulating material and includes a surrounding wall main body 55a a lower end face of which is formed in a cylindrical shape along a peripheral edge portion of the circuit arrangement surface 52a, and a skirt portion 55b extending from a peripheral edge portion of the surrounding wall main body 55a in a lower direction to cover a peripheral side face of the heat radiating member 52.

The surrounding wall main body 55a has a shape of surrounding the circuit arrangement region of the heat radiating member 52 and is formed a seal member filling groove 54 over an entire periphery of the lower end face. That is, the seal member filling groove 54 is provided to surround the circuit arrangement region of the circuit arrangement surface 52a to be filled with the seal member 53, described later. Although a section of the seal member filling groove 54 is not particularly limited, the section is formed substantially in a U shape also in the second embodiment similar to the first embodiment.

Further, the surrounding wall main body 55a is formed such that a height of a peripheral side wall thereof is set to be at least higher than leg-like terminals 61a of the various electronic parts (FET) 61 mounted to the power circuit section 51 and to be able to surround the power circuit section 51 including the various electronic parts 61. In the second embodiment, the height of the peripheral side wall of the surrounding wall main body 55a is set to be higher than the electronic part 61.

Further, the surrounding wall main body 55a is provided such that an upper end opening 55c thereof substantially faces the circuit arrangement region of the circuit arrangement surface 52a. After the surrounding wall member 55 is attached to the heat radiating member 52, it is possible for an operator to visually recognize the power circuit section 51 arranged in the heat radiating member 52 via the upper end opening portion 55c.

Further, the surrounding wall main body 55a includes through holes 62 for terminals, to which the external connection terminal 64 of the power circuit section 51 is inserted, to penetrate the surrounding wall main body 55a in an up and down direction on two left and right sides of the upper end opening portion 55c. A plurality of hoods 58 for forming connectors are projected from the upper face of the surrounding wall main body 55a to a side opposed to the heat radiating member 52 to surround the plurality of through holes 62 for terminals. That is, the hoods 58 are aligned along a longitudinal direction of the surrounding wall member 55 on the two left and right sides of the upper end opening portion 55c and constituted such that one or a plurality of external connection terminals 64 can be projected into the hoods 58. The hoods 58 and one or the plurality of external connection terminal 64 constitute an external connection connector, which can connect with another connector.

On the other hand, at inside of the hood 58, as shown in FIG. 9, a connector contact face in contact with a front end face of other connector remains at the upper face of the surrounding wall main body 55a and a recess portion 65 for storing resin recessed into a lower side (side of the heat radiating member 52) of the connector contact face is formed. The through hole 62 for terminal is provided in a region at which the recess portion 65 for storing resin is formed. Further, in a part of the hoods 58, resin inserting holes 66 communicating from the recess portions 65 for storing resin to an inner side of the surrounding wall main body 55a are formed.

The recess portion 65 for storing resin is provided for introducing and puring a waterproofing resin, described later, via the through 62 for terminal. In the recess portion 65 for storing resin, a waterproof layer 56 described later is formed to prevent water from entering through the through hole 62 for terminal and to effectively prevent short-circuit of the power circuit section 51. Therefore, the waterproofing resin, described later, overflows to the recess portion 65 for storing resin via the through hole 62 for terminal. On the other hand, the resin inserting hole 66 assists and intensifies to introduce the waterproofing resin from the through hole 62 for terminal. The waterproofing resin is introduced into the recess portion 65 for storing resin via the resin inserting hole 66.

With the circuit arrangement surface 52a as a reference, a height to a bottom face of the recess portion 65 for storing resin is set to be higher than that of an upper edge of the leg-like terminal 61a of the electronic part (FET) 61 at least with the same reference. Therefore, when the waterproofing resin is overflowed to the recess portion 65 for storing resin via the resin inserting hole 66, in the surrounding wall main body 55a, the leg-like terminal 61a of the electronic part is sealed by the waterproofing resin. In the second embodiment, whereas with the circuit arrangement surface 52a as a reference, the height up to the bottom face of the recess portion 65 for storing resin is set to be substantially equivalent to that of the upper end of the electronic part 61, a height up to an upper edge of the recess portion 65 for storing resin is set to be higher than that of the upper end of the electronic part.

In the recess portion 65 for storing resin, a plurality of through holes 62 for terminals maybe disposed or one through hole 62 for terminal may be disposed. Further, even when the plurality of through holes 62 for terminals are disposed in the recess portion 65 for storing resin, not only all of the through holes 62 for terminals in the hood 58 may be formed in one recess portion 65 for storing resin but a part of the through holes 62 for terminals in the hood 58 may be formed in one recess portion 65 for storing resin. Further, even when the plurality of through holes 62 for terminals are formed in the recess portion 65 for storing resin, a rib may be formed between the through holes 62 for terminals and contiguous ones of the recess portions 65 for storing resin on two sides of the rib may be communicated with each other therethrough.

Further, a portion of the hood 58 located at a lower end portion thereof at a time when disposed vertically is formed to locally bulge to an outer side and a drain hole 58b opened to a side of the heat radiating member 52 is formed at the surrounding wall main body 55a in the bulged portion 58a. The drain hole 58b discharges water stored in the hood 58. Water discharged from the drain hole 58b is made to discharge to outside via a water discharge path 70 between the heat radiating member 52 and the surrounding member 55.

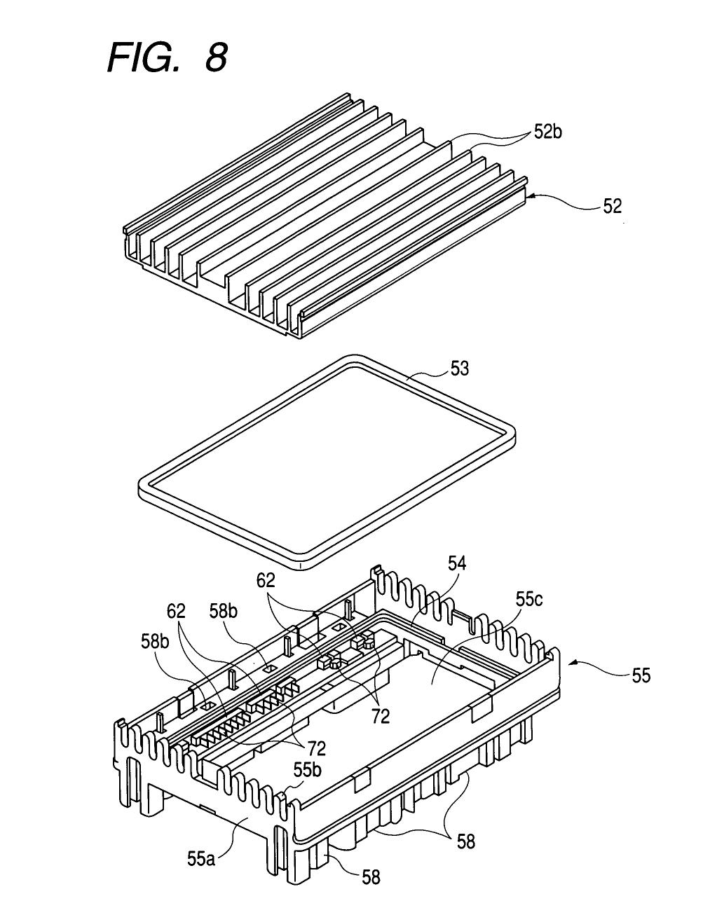

Further, the surrounding wall main body 55a includes a draining notch 71 at a lower portion thereof at a time when the power module is vertically arranged and the draining notch 71 is provided to be opposed to a surface of the waterproofing layer 56, described later, or on an upper side of the surface of the waterproofing layer 56. Further, numeral 72 in FIG. 8 designates a pushing projected portions for pushing to hold the bus bar 60 constituting the external connection terminal 64.

On the other hand, the skirt portion 55b is formed in a frame member shape covering four peripheral side faces of the heat radiating member 52. A pair of wall portions facing to each other are formed in a shape of recesses and projections in correspondence with the shape of the heat radiating fins 52b. Further, a locking claw 73 for locking is formed at a pertinent location of the skirt portion 55 in correspondence with the heat radiating member 52 to thereby enable to solidly assemble the surrounding wall member 55 and the heat radiating member 52.

The seal member 53 is formed similar to the seal member 3 according to the first embodiment except that shapes thereof differ from each other. Therefore, an explanation thereof will be omitted here.

The surrounding wall member 55 having the above-described constitution is attached to the heat radiating member 52 as follows.

First, the seal member filling groove 54 of the surrounding wall member 55 is filled with the seal member 53 in a tight state. The power circuit section 51 is assembled to the surrounding wall member 55 by inserting the external connection terminal 64 into the through hole 62 for terminal. Next, an adhering agent same as the adhering agent constituting the insulating layer 80 is coated at the circuit arrangement region of the heat radiating member 52. The surrounding wall member 55 assembled with the power circuit section 51 is attached to the heat radiating member 52 in a state of surrounding the circuit arrangement region of the heat radiating member 52 and bringing the seal member 53 into close contact with the circuit arrangement surface 52a. Thereby, the power circuit section 51 is bonded to the circuit arrangement region of the heat radiating member 52.

In attaching the surrounding wall member 55 to the heat radiating member 52, attachment is carried out by locking the locking claw 73 of the skirt portion 55b to the corresponding portion of the heat radiating member 52. However, similar to the first embodiment, a publicly-known attaching method may be adopted. Further, when the waterproofing resin described later having adhering performance is used, the surrounding wall member 55 may be attached to the heat radiating member 50 by temporarily fixing.

On the other hand, in attaching the power circuit section 51 to the circuit arrangement region of the heat radiating member 52, an adhering agent which is an adhering agent having high heat conductivity and is same as the adhering agent constituting the insulating layer 80 (epoxy species adhering agent according to the second embodiment) is coated. However, it is needless to say that the adhering agent may naturally be other adhering agent.

Further, thereafter, the power circuit section 51 is solidly bonded to the circuit arrangement region of the heat radiating member 52 by pressing a pertinent location of the power circuit section 51, particularly, pressing the peripheral edge portion and a periphery of the electronic part (FET) 61 via the upper end opening portion 55c of the surrounding wall member 55. By pressing the power circuit section 51 to bond with the heat radiating member 52 in this way, the bus bar 60 disposed at a rear face of the power circuit section 51 is embedded in the adhering agent to firmly prevent short-circuit between the bus bars 60 by insulating performance of the adhering agent and heat conductivity between the power circuit section 51 and the heat radiating member 52 can be enhanced.

Accordingly, the power circuit section 51 is arranged at the circuit arrangement region on the circuit arrangement surface 52a of the heat radiating member 52. The surrounding wall member 55 surrounds the circuit arrangement region on the circuit arrangement surface 52a of the heat radiating member 52 including the power circuit section 51 to form a surrounding wall. Therefore, the surrounding wall functions as a dam with respect to the waterproofing resin.

3) Waterproofing layer forming step

After the surrounding wall forming step and the circuit arranging step as described above, the waterproofing layer 56 is formed by pouring a predetermined amount of a waterproofing resin in a liquid state into a space surrounded by the surrounding wall member 55 and curing the waterproofing resin.

Specifically, first, the heat radiating member 52 which the surrounding wall member 55 is attached to and the power circuit section 51 is arranged on is set such that a side of the circuit arrangement surface 52a thereof is directed to an upper side. The waterproofing resin in the liquid state is poured from the upper end opening portion 55c of the surrounding wall member 55. The waterproofing resin is poured until the various electronic parts (FET) 61 mounted to the power circuit section 51 are sealed. At this occasion, the waterproofing resin poured from the upper end opening portion 55c of the surrounding wall member 55 is set to overflow into the hood 58 via the through hole 62 for terminal and the resin inserting hole 66 to reach a predetermined height in the recess portion 65 for storing resin.

In the state of being filled with the waterproofing resin, the bus bar 60 including a base end portion of the external connection terminal 64 and the control circuit board 63 are also sealed by the waterproofing resin. On the other hand, since the circuit arrangement region is surrounded by the seal member 53, even the waterproofing resin in the liquid state does not leak out from the clearance between the heat radiating member 52 and the surrounding member 55.

Although the waterproofing resin may only be provided with waterproofing performance and a material thereof or the like is not particularly limited, by using the resin in the liquid state as in the second embodiment, the waterproofing resin spreads to corners of the surrounding wall member 55 and the sealing can firmly be carried out. Further, when the waterproofing resin having constant elastic performance and shape holding performance even after having been cured is used, influence effected on the electronic part (FET) 61 or the like is inconsiderable and the electronic part (FET) 61 or the like is maintained in a sealed state and therefore, such a waterproofing resin is preferable. Further, it is preferable to use an epoxy species resin or the like from a view point that not only the epoxy species resin is excellent in heat resistance and cold resistance but also electric insulating performance thereof is improved. Further, the waterproofing resin having adhering performance can also be adopted. Further, when the waterproofing resin excellent in heat conductivity is adopted, not only heat radiation by the heat radiating member 52 is accelerated but heat is radiated also from the waterproofing layer 56 and the waterproofing resin further excellent in heat radiating performance can be constituted.

Further, the poured waterproofing resin is heated and cured to form the waterproofing layer 56.

4) Lid member attaching step

Further, a lid member 57 for covering the upper end opening portion 55c of the surrounding wall member 55 is fabricated. After forming the waterproofing layer 56, the lid member 57 is attached to the surrounding wall member 15 in a state of covering the upper end opening portion 55c.

The lid member 57 has a plate-like shape in correspondence with the upper end opening portion 55c of the surrounding wall member 55 and is attached to the surrounding wall member 55 by a locking structure, not illustrated, or is attached to the surrounding wall member 55 by adhering, welding or the like. Further, although the lid member 57 can pertinently be omitted, it is preferable to provide the lid member 57 from a view point of avoiding inside of the surrounding wall member 55 from being exposed and protecting the power circuit section 51 against outside shock.

### Other Embodiment

Further, although an explanation has been given of the method of waterproofing the power circuit section 1 according to the embodiment as described above, the waterproofing method according to the invention is not limited to the above-described embodiments but can variously be modified within a range not deviated from a gist thereof. For example, the following modifications are possible.

The order of the respective steps is not limited to those of the above-described embodiments but, for example, the surrounding wall forming step may be carried out after the circuit arranging step or the like. However, when the circuit arranging step is carried out after the surrounding wall forming step or the circuit arranging step is carried out along with the surrounding wall forming step, positioning of the power circuit section 1 is facilitated, which is advantageous in promoting operational efficiency.

Further, although according to the above-described embodiments, a thermosetting resin is used as the waterproofing resin and the waterproofing layer 6 or 56 is formed by thermally curing the waterproofing resin, the method of forming the waterproofing layer 6 or 56 is not limited to the method but the waterproofing layer 6 or 56 may be formed by naturally curing the waterproofing resin by leaving the poured water proofing resin for a predetermined period of time.

Further, the surrounding wall member 5 according to the first embodiment may be formed to be higher than the height of the waterproofing layer 6, and a single piece or a plurality of drain holes may be provided to be disposed to be opposed to the surface of the waterproofing layer 6 at the lower portion of the surrounding wall member 5 when the power module is arranged vertically or to be disposed above the surface of the waterproofing layer 6.

As described above, the invention includes a circuit arranging step of arranging a power circuit section provided with a single piece or a plurality of electronic parts having leg-like terminals at a circuit arrangement region above a circuit arrangement surface of a heat radiating member, a surrounding wall forming step of attaching a surrounding wall member comprising an insulating material, having a seal member at an end face thereof on a side of the heat radiating member and capable of surrounding the power circuit section including the leg-like terminals of the electronic parts in a state of surrounding the circuit arrangement region and bringing the seal member into close contact with the circuit arrangement surface, and a waterproofing layer forming step of forming a waterproofing layer by pouring a waterproofing resin in a liquid state into a space surrounded by the surrounding wall member to seal at least the leg-like terminals of the electronic parts and curing the waterproofing resin after the circuit arranging step and the surrounding wall forming step, and therefore, a surrounding wall functioning as a dam can be formed by only attaching the surrounding wall member comprising the insulating material to the heat radiating member and effective waterproofing of the power circuit section can be achieved by a simple method of pouring the waterproofing resin in the liquid state in the space surrounded by the surrounding wall and curing the waterproofing resin. Further, the waterproofing layer can firmly be formed over a total of the power circuit section by the waterproofing resin in the liquid state, the surrounding wall member is attached thereto in a state of bringing the seal member into close contact with the circuit arrangement surface of the heat radiating member and therefore, the waterproofing resin in the liquid state can be prevented from being leaked and therefore, the leg-like terminal of the electronic part can firmly be sealed by only pouring a predetermined amount of the waterproofing resin. Further, waterproofing of the power circuit section can be achieved by forming the waterproofing layer by curing the waterproofing resin and therefore, the power module including the power circuit section can compactly be formed and also a request for the small-sized formation of the power module can be satisfied.

What is claimed is:

1. A power module comprising:
a heat radiating member including a circuit arrangement surface having a circuit arrangement region;
a power circuit section including at least one electronic part and arranged in the circuit arrangement region;
a wall member surrounding the circuit arrangement region; and
a resin layer disposed in a space defined by the wall member and the heat radiating member, wherein:
the electronic part has a plurality of leg portions; and
the resin layer seals at least the leg portions.

2. The power module according to claim 1, further comprising:
a seal member surrounding the circuit arrangement region, wherein:
the wall member defines a first groove to which the seal member is fitted; and
the seal member is interposed between the wall member and the heat radiating member.

3. The power module according to claim 1, wherein:
the power circuit section includes at least one bus bar;
the wall member includes a hood; and
an end portion of the bus bar is inserted into the hood.

4. The power module according to claim 3, wherein:
the wall member further includes a through hole communicating a side of the heat radiating member and a side of the hood; and
a part of the bus bar passes through the through hole.

5. The power module according to claim 4, wherein:
the wall member further includes:
a recess portion; and
another through hole communicating the side of the heat radiating member and the recess portion.

6. The power module according to claim 3, wherein:
the bus bar has:
a first portion extending in parallel with the circuit arrangement surface; and
a second portion standing up from the circuit arrangement surface and inserted into the hood.

7. The power module according to claim 3, wherein:
the wall member defines a second groove;
the bus bar has:
a first portion extending in parallel with the circuit arrangement surface;
a second portion standing up from the circuit arrangement surface; and
a third portion extending through the second groove.

8. The power module according to claim 3, wherein the bus bar protrudes from at least one of side edges of the power circuit section in outward directions.

9. The power module according to claim 1, further comprising:
an insulating layer disposed between the heat radiating member and the power circuit section.

10. The power module according to claim 9, wherein the insulating layer is thermally connected with the heat radiating member and the power circuit section.

11. The power module according to claim 1, further comprising:
a lid attached to the wall member to cover the power circuit section.

12. The power module according to claim 1, further comprising a bus bar constitution plate including a plurality of bus bars, wherein:
the electronic part is electrically connected to the power circuit section and at least one of the bus bars.

13. A method for waterproofing a power circuit section, comprising:
arranging the power circuit section including at least one electronic part having a plurality of leg portions in a circuit arrangement region on a circuit arrangement surface of a heat radiating member;
attaching a wall member, which is made of an insulating material and includes a seal member at an end surface on a side of the heat radiating member, to the heat radiating member in a state where the wall member surrounds the circuit arrangement region and the seal member is closely contacted with the circuit arrangement surface;
pouring a liquid resin into a space surrounded by the wall member and the heat radiating member until at least the leg portions of the electronic part are sealed; and
curing the resin to form a waterproof layer.

14. The method according to claim 13, wherein:
the wall member includes a groove on the side of the heat radiating member; and
in the attaching step, the wall member is attached to the heat radiating member after the seal member is attached to the groove.

15. The method according to claim 14, wherein the seal member is a foam rubber.

16. The method according to claim 13, wherein the resin is a silicone resin.

17. The method according to claim 13, further comprising:
attaching a lid to an opening portion of the wall member to cover the opening portion, wherein the opening portion is formed on an opposite side of the wall member to the heat radiating member.

18. The method according to claim 13, wherein:
the power circuit section includes:
a bus bar constitution plate on which a plurality of bus bars are arranged in a predetermined pattern;
an electronic part disposed on the bus bar constitution plate; and
a control circuit board for controlling a switching operation of the electronic part, the control circuit board bonded to one surface of the bus bar constitution plate;
the electronic part is mounted to the bus bar constitution plate and the control circuit board; and
in the pouring step, the resin is poured until the bus bar constitution plate and the control circuit board are sealed.

19. A method for waterproofing a power circuit section, comprising:
fitting a seal member into a groove portion of a cylindrical wall member tightly;
attaching the power circuit section to the wall member;
coating an adhesive agent on a circuit arrangement region of a heat radiating member;
attaching the heat radiating member to the wall member so that the wall member surrounds the circuit arrangement region and the seal member closely contacts with the heat radiating member, to attach the power circuit section to the circuit arrangement region;
pouring a liquid resin into a space defined by the heat radiating member and the wall member; and
curing the resin to form a waterproof layer.

20. The method according to claim 19, further comprising:
attaching a lid to an opening portion of the wall member to cover the opening portion, wherein the opening portion is formed on an opposite side of the wall member to the heat radiating member.
